(19) United States
(12) Patent Application Publication
(10) Pub. No.: US 2024/0314990 A1
(43) Pub. Date: Sep. 19, 2024

(54) ON DIE CLOCK JITTER INJECTION FOR ELECTROMAGNETIC INTERFERENCE REDUCTION

(71) Applicant: Micron Technology, Inc., Boise, ID (US)

(72) Inventor: Eric J. Stave, Meridian, ID (US)

(21) Appl. No.: 18/523,591

(22) Filed: Nov. 29, 2023

Related U.S. Application Data
(60) Provisional application No. 63/451,830, filed on Mar. 13, 2023.

(51) Int. Cl. H05K 9/00; G11C 11/408

(52) U.S. Cl. CPC H05K 9/0071; G11C 11/4087

(57) ABSTRACT

This disclosure is directed to circuitry for inducing jitter to clock signal of an electronic device to reduce undesired electromagnetic emissions of the electronic device during operation. The electronic device may include a jitter generator to induce the jitter to the clock signal. In some embodiments, the electronic device may also include a multiplexer outputting either of the clock signal or the jittered clock signal for latching the output signals. As such, the output signals may have a baseline margin based on the clock signal while the electronic device may operate using the jittered clock signal. The jittered clock signal may spread the undesired electromagnetic emissions of the electronic device and therefore reduce interference.

### CROSS-REFERENCE TO RELATED APPLICATIONS

This application claims priority to U.S. Provisional Application No. 63/451,830, filed Mar. 13, 2023, entitled “ON DIE CLOCK JITTER INJECTION FOR ELECTROMAGNETIC INTERFERENCE REDUCTION,” which is incorporated by reference herein in its entirety for all purposes.

### BACKGROUND

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light and not as admissions of prior art.

The following relates generally to reducing electromagnetic emissions of an electronic device. For example, an electronic device (e.g., a digital circuit) may include a number of electronic components. Moreover, the electronic device may operate based on receiving a clock signal. The clock signal may toggle based on a clock frequency. As such, the electronic device may communicate information between the electronic components at a rate of the clock frequency. However, in some cases, the electronic device may emit undesired electromagnetic emissions during operation.

### BRIEF DESCRIPTION OF THE DRAWINGS

Various aspects of this disclosure may be better understood upon reading the following detailed description and upon reference to the drawings in which:

FIG. 1 is an electronic device including a jitter generator to reduce an electromagnetic interference of the electronic device, in accordance with an embodiment of the present disclosure;

FIG. 2 is a graph depicting distribution of the undesired electromagnetic signals of the electronic device discussed above when operating based on the clock signal and the jittered clock signal, in accordance with an embodiment of the present disclosure;

FIG. 3 is a memory device including the jitter generator to reduce the electromagnetic interference of the memory device, in accordance with an embodiment of the present disclosure; and

FIG. 4 is a block diagram of an example implementation of a memory system including multiple memory devices of FIG. 3 on a circuit board, in accordance with an embodiment of the present disclosure.

### DETAILED DESCRIPTION

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements. One or more specific embodiments of the present embodiments described herein will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

This disclosure is directed to reducing electromagnetic interference (EMI) of an electronic device and/or an electronic system including multiple electronic devices. An electronic device of the electronic system may include one or more circuit components operating based on a clock signal having a core clock frequency. For example, an oscillator may provide the clock signal to the electronic device. In some cases, a circuit component, multiple circuit components, and/or a combination of the circuit components of the electronic device may emit undesired electromagnetic signals at and/or near the core clock frequency during operation.

If not compensated for, a peak emission power of the undesired electromagnetic signals may exceed a high threshold (e.g., a peak emission power threshold). The electronic device may emit the undesired electromagnetic signals having the peak emission power concentrated at or near the core clock frequency. Moreover, the threshold may be associated with electromagnetic interference with one or more circuit components of the electronic device, electromagnetic interference with one or more other electronic devices, a standard for high electromagnetic radiation threshold, among other things.

Inducing jitter to the clock signal may spread the undesired electromagnetic signals across a wider frequency spectrum around the core clock frequency. For example, the electronic device may emit the undesired electromagnetic signals at a wider frequency range around the core clock frequency during operation based on a jittered clock signal. As such, inducing jitter to the clock signal of the electronic device may reduce the peak emission power of the electronic device by spreading the concentration of the undesired electromagnetic signals across the wider frequency spectrum.

The jittered clock signal may include the clock signal having positive or negative jitters with different values. The positive or negative jitters may have random values, controlled and/or uncontrolled values, increasing and/or decreasing values, among other possibilities. Accordingly, in some cases, inducing jitter to the clock signal of the electronic device may reduce the peak emission power of the electronic device below the threshold. The electronic device may include a jitter generator to induce jitter to the clock signal.

In some embodiments, multiple electronic devices of an electronic system may include respective jitter generators. For example, an oscillator may provide the clock signal having the core clock frequency to the multiple electronic devices of the electronic system. Moreover, the jitter generators of each of the electronic devices may induce jitter (e.g., randomly induce jitter) to the received clock signal. As such, each electronic device may operate based on a different jittered clock signal. Such electronic devices may each emit the undesired electromagnetic signals having different frequencies during operation. For example, the jittered clock signals may each have a different clock frequency compared to the core clock frequency (e.g., ±1 Hertz (Hz), ±3 Hz, ±50 Hz, and so on).

As such, inducing jitter to the clock signals of multiple electronic devices of an electronic system may reduce a cumulative peak emission power of the electronic system. Moreover, inducing jitter to the clock signal of one or multiple electronic devices may improve operations of the one or more electronic devices and/or the electronic system including the one or more electronic devices by reducing the electromagnetic interference of the one or more electronic devices.

FIG. 1 is an electronic device 10 including a jitter generator 12 (e.g., an on-die jitter generator 12) to reduce an electromagnetic interference of the electronic device 10. The electronic device 10 may also include a clock input buffer 14, a multiplexer 16, control circuitry 18, and data input/output circuit 20 (e.g., DQ pins 20). It should be appreciated that the electronic device 10 is shown by the way of example and in alternative or additional embodiments, the electronic device 10 may include additional, reduced, or different circuitry. Moreover, the electronic device 10 may include a memory device, a processing and/or controller device, among other things.

The clock input buffer 14 may receive a clock signal 22 having a core clock frequency, for example, from an oscillator. The oscillator may be disposed on the electronic device 10 and/or disposed external to the electronic device 10. In some embodiments, the clock input buffer 14 may include and/or may be coupled to a data buffer circuit. As such, the clock input buffer 14 may latch and provide input data 24 to the control circuitry 18 at a rate of the core clock frequency. For example, the input data 24 may include command data, address data, read/write data, activation and/or deactivation data, among other data.

Moreover, the clock input buffer 14 may provide the clock signal 22 to the jitter generator 12. The jitter generator 12 may generate a jittered clock signal 26 by inducing jitter to the received clock signal 22. The jitter generator 12 may provide the jittered clock signal 26 to the control circuitry 18 and the multiplexer 16. In some embodiments, the jitter generator 12 may be enabled by a fuse (not shown). Advantageously, the jitter generator 12 may be arranged in close proximity to the clock input buffer 14 such that jitter may be induced before the clock signal 22 is sent to the control circuitry 18.

The jitter generator 12 may include any viable circuitry to generate the jittered clock signal 26 in response to receiving the clock signal 22. For example, in some embodiments, the jitter generator 12 may include a random number generator to generate a random number in response to the clock signal 22. Moreover, the jitter generator 12 may include delay-causing circuitry to receive the clock signal 22. The delay-causing circuitry may create a delayed clock signal. Furthermore, the jitter generator 12 may include a phase mixer to receive the random number, the delayed clock signal, and the clock signal 22. The phase mixer may generate the jittered clock signal 26 by inducing random jitter on the clock signal 22. As such, the phase mixer may output the jittered clock signal 26 to the control circuitry 18. Moreover, the phase mixer may output the clock signal 22 and the jittered clock signal 26 to the control circuitry 18 and the multiplexer 16, as will be appreciated.

The control circuitry 18 may include various circuit components such as command decoders, memory banks, control circuits, data paths, data registers, delay locked loops (DLLs), input/output interfaces, among other things. Moreover, in different embodiments, the control circuitry 18 may perform different operations. For example, the circuit components in the control circuitry 18 may include a processor, a controller, and/or a memory device, among other things. The circuit components of the control circuitry 18 may communicate information via electrical signals to generate output data 28. Moreover, the control circuitry 18 may communicate the information and provide the output data 28 based on the jittered clock signal 26 having the core clock frequency.

The control circuitry 18 may emit undesired electromagnetic signals with reduced peak emission power at or near the core clock frequency during operation. In some cases, performing operations by the control circuitry 18 based on the jittered clock signal 26 in lieu of the clock signal 22 may reduce the peak emission power of the undesired electromagnetic signals. As discussed above, inducing jitter to a clock signal (e.g., the clock signal 22) of an electronic device, such as the electronic device 10 and/or the control circuitry 18, may spread a concentration of the undesired electromagnetic signals across a wider frequency spectrum.

As such, the control circuitry 18, and therefore the electronic device 10, may emit the undesired electromagnetic signals with reduced peak emission power during operation. In some embodiments, the control circuitry 18 and/or the electronic device 10 may emit the undesired electromagnetic signals with the reduced peak emission power below a peak emission power threshold (e.g., below −6 decibels (dB), −3 dB, 0 dB, 1 dB, and so on). In any case, the control circuitry 18 may provide the output data 28 to the input/output circuit 20.

As mentioned above, the jitter generator 12 may output the clock signal 22 and the jittered clock signal 26 to the multiplexer 16. In turn, the multiplexer 16 may output the clock signal 22 or the jittered clock signal 26 to the input/output circuit 20. In some embodiments, the multiplexer 16 may receive selection signals 30 indicative of outputting the clock signal 22 or the jittered clock signal 26 to the input/output circuit 20. For example, the control circuitry 18, an external controller, among other things, may provide the selection signals 30. In alternative embodiments, the multiplexer 16 may be omitted such that the jitter generator 12 outputs the jittered clock signal 26 directly to the input/output circuit 20. Further, the multiplexer 16 is provided as one example of a selector circuit. Any circuit capable of providing a selected clock signal based on the selection signals 30 may be utilized.

In some cases, the control circuitry 18 may generate the output data 28 with a degree of margin distortions (e.g., in the rising/falling edge margins) when operating based on the jittered clock signal 26. Moreover, in specific cases, the output data 28 may have a distorted margin higher than a threshold (e.g., higher than 2%, higher than 3%, and so on) compared to the clock signal 22. In such cases, the selection signals 30 may indicate outputting the clock signal 22 by the multiplexer 16. As such, the multiplexer 16 may output the clock signal 22 to the input/output circuit 20 for latching the output data 28.

Accordingly, the input/output circuit 20 may latch the output data 28 based on receiving the clock signal 22 to correct the distorted margins of the output data 28. Alternatively, in some cases, the selection signals 30 may indicate outputting the jittered clock signal 26 to the input/output circuit 20. In such cases, the input/output circuit 20 may latch the output data 28 based on receiving the jittered clock signal 26 to correct the distorted margins of the output data 28. In any case, the input/output circuit 20 may provide the output data 28 to one or more external devices. In some embodiments, the electronic device 10 may include a memory device. In such embodiments, the output data 28 may include memory commands, memory responses, retrieved data, among other things.

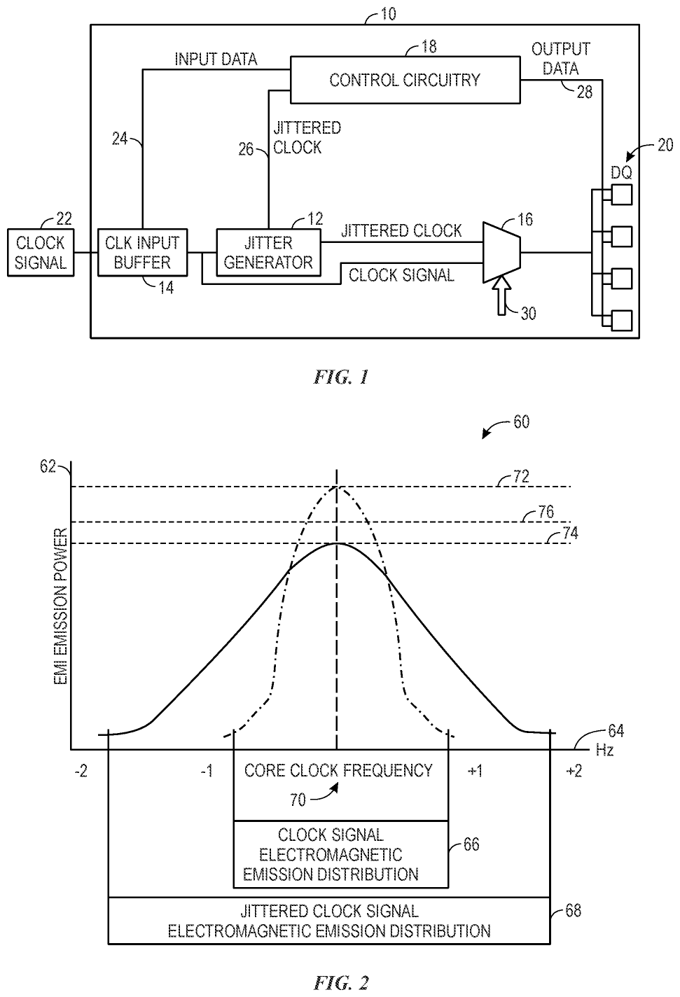

FIG. 2 is a graph 60 depicting emission distribution of the undesired electromagnetic signals of the electronic device 10 discussed above. In particular, graph 60 depicts an emission power 62 of the electronic device 10 across a frequency spectrum 64. The electronic device 10 may emit the undesired electromagnetic signals having a clock signal emission distribution 66 during operation based on the clock signal 22. The electronic device 10 may emit the undesired electromagnetic signals having a jittered clock signal emission distribution 68 during operation based on the jittered clock signal 26. For example, the jittered clock signal emission distribution 68 may be associated with the embodiment of FIG. 1 discussed above.

The frequency spectrum 64 may include a core clock frequency 70 associated with the clock signal 22 and the jittered clock signal 22. For example, the core clock frequency may have a frequency value of 100 Hz, 1 Kilohertz, 1 Megahertz, 1 Gigahertz (GHz), 2 GHZ, among other possible frequency values. The clock signal emission distribution 66 may be measured when the electronic device 10 is operating based on the clock signal 22. Moreover, the jittered clock signal emission distribution 68 may be measured when the electronic device 10 is operating based on the jittered clock signal 26. In some cases, the clock signal emission distribution 66 and the jittered clock signal emission distribution 68 may be measured at a surface of the electronic device 10. Alternatively or additionally, the clock signal emission distribution 66 and the jittered clock signal emission distribution 68 may be measured at a proximity of the electronic device 10.

A first peak emission power 72 is associated with the electronic device 10 operating based on receiving the clock signal 22. A second peak emission power 74 is associated with the electronic device 10 operating based on receiving the jittered clock signal 26. As shown, the electronic device 10 may emit the undesired electromagnetic signals having the second peak emission power 74 lower than the first peak emission power 72 when operating using the jittered clock signal 26. As such, inducing jitter to a clock signal of the electronic device 10 during operation may spread the concentration of the undesired electromagnetic signals across a wider frequency spectrum (e.g., ±1 Hz, ±2 Hz, and so on).

Moreover, in some cases, the second peak emission power 74 may be lower than a threshold 76 (e.g., below −6 decibels (dB), −3 dB, 0 dB, 1 dB, and so on) while the first peak emission power 72 may be above the threshold 76. For example, the threshold 76 may be associated with electromagnetic interference with one or more circuit components of the electronic device 10, electromagnetic interference with one or more other electronic devices, a standard for high electromagnetic radiation threshold, among other things. In some cases, the threshold 76 may also be associated with emission power measured at the surface and/or proximity of the electronic device 10 (e.g., in dB or any other viable measurement unit). Accordingly, inducing jitter (e.g., by the jitter generator 12 discussed above) to the clock signal 22 of the electronic device 10 may reduce the peak emission power of the electronic device 10 below the threshold.

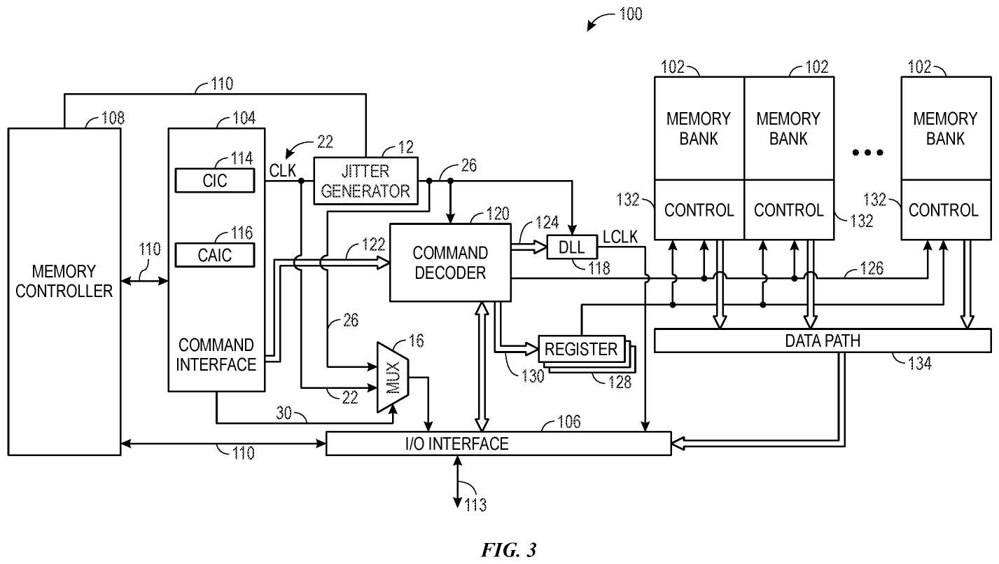

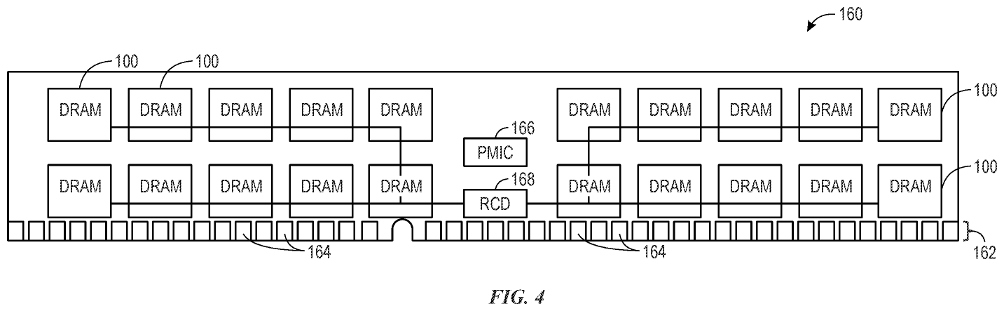

FIG. 3 is a block diagram illustrating certain features of a memory device 100 including the jitter generator 12. For example, the electronic device 10 discussed above may include the memory device 100 having the jitter generator 12. In some embodiments, a memory subsystem of an apparatus may include the memory device 100. The apparatus may include other subsystems such as processing circuitry including one or more processors, programmable logic circuits, hardened logic circuitry, or a combination thereof, among other things.

In any case, the block diagram of FIG. 3 depicts a functional block diagram illustrating certain functionality of the memory device 100. In accordance with one embodiment, the memory device 100 may include a random access memory (RAM) device, a ferroelectric RAM (FeRAM) device, a dynamic RAM (DRAM) device, a static RAM (SRAM) device (including a double data rate SRAM device), flash memory, and/or a 3D memory array including phase change (PC) memory and/or other chalcogenide-based memory, such as self-selecting memories (SSM). Moreover, each memory cell of such memory devices may include a corresponding logic storing device (e.g., a capacitor, a resistor, or the resistance of the chalcogenide material(s)).

The memory device 100 may include a number of memory banks 102 each inclusive of one or more memory arrays. For example, the memory banks 102 may be disposed in multiple columns and rows. Various configurations, organizations, and sizes of the memory banks 102 on the memory device 100 may be used based on an application and/or design of the memory device 100 within an electrical system.

In different embodiments, the memory banks 102 may include a different number of rows and/or columns of memory cells. Moreover, the memory banks 102 may each include a number of pins for communicating with other blocks of the memory device 100. As such, a number of transceivers and data lines (e.g., one or more data buses) may be coupled to each memory bank 102. For example, each memory bank 102 may receive one data bit per pin at each clock cycle from a data line and/or transceiver.

The memory device 100 may also include a command interface 104, the jitter generator 12, and an input/output (I/O) interface 106 (I/O circuit). The command interface 104 is configured to provide a number of signals received from a processor (e.g., a processor subsystem of an apparatus) or a controller, such as a memory controller 108. In different embodiments, the memory controller 108, hereinafter controller 108, may include one or more processors (e.g., memory processors), one or more programmable and/or hardened logic fabrics, or any other suitable processing components.

In some embodiments, a bus 110 may provide a signal path or a group of signal paths to allow bidirectional communication between the controller 108, the jitter generator 12, and/or the command interface 104. For example, the controller 108 may receive memory access requests from the I/O interface via the command interface 104 and the bus 110. Moreover, the controller 108 may provide the access commands and/or access instructions for performing memory operations to the command interface 104 via the bus 110.

Similarly, an external bus 112 may provide another signal path or group of signal paths to allow for bidirectional transmission of signals, such as data signals and access commands (e.g., read/write requests), between the I/O interface 106, the controller 108, a command decoder 120, and/or other components. Thus, the controller 108 may provide various signals (e.g., the access commands, the access instructions, or other signals) to different components of the memory device 100 to facilitate the transmission and receipt of data to be written to or read from the memory banks 102.

The command interface 104 may receive different signals from the controller 108. For example, a reset command may be used to reset the command interface 104, status registers, state machines and the like, during power-up. Various testing signals may also be provided to the memory device 100. For example, the controller 108 may use such testing signals to test connectivity of different components of the memory device 100. In some embodiments, the command interface 104 may also provide an alert signal to the controller 108 upon detection of an error in the memory device 100. Moreover, the I/O interface 106 may additionally or alternatively be used for providing such alert signals, for example, to other system components electrically connected to the memory device 100.

The command interface 104 may receive one or more clock signals from an external device (e.g., an external clock signal). The command interface 104 may include a clock input circuit 114 (CIC) and a command address input circuit 116 (CAIC). The command interface 104 may use the clock input circuit 114 and the command address input circuit 116 to receive the input signals, including the access commands, to facilitate communication with the memory banks 102 and other components of the memory device 100. For example, the clock input buffer 14 of FIG. 1 discussed above may include the clock input circuit 114, the command address input circuit 116, or both.

Moreover, the clock input circuit 114 may receive the one or more clock signals (e.g., the external clock signal) and may generate the clock signal 22 (e.g., an internal clock signal, CLK) therefrom. In the depicted embodiment, the command interface 104 may provide the clock signal 22 to the jitter generator 12. As such, the jitter generator 12 may output the jittered clock signal 26 based on receiving the clock signal 22. In the depicted embodiment, the jitter generator 12 may output a clock signal with added jitter (e.g., the jittered clock signal 22) to the command decoder 120, a DLL 118, and/or the I/O interface 106.

As mentioned above, in some embodiments, the jitter generator 12 may include a random number generator to generate a random number when receiving the clock signal 22. The jitter generator 12 may also include delay-causing circuitry to receive the clock signal 22, where the delay-causing circuitry may create a delayed clock input signal. The jitter generator 12 may also include a phase mixer to receive the random number, the delayed clock signal, and the clock signal 22, where the phase mixer outputs the jittered clock signal 26 having the clock signal 22 with induced jitter.

With the foregoing in mind, the DLL 118 may generate a phase controlled internal clock signal (LCLK) based on receiving the clock signal 22 and/or the jittered clock signal 26. For example, the DLL 118 may generate a phase controlled internal clock signal based on the jittered clock signal 26. The jittered clock signal 26 may cause inducing jitter on the phase controlled internal locked clock signal.

In alternative or additional embodiments, the DLL 118 may generate and provide a phase controlled internal clock signal to the jitter generator 12 based on receiving the clock signal 22 (not shown for simplicity). In such embodiments, the jitter generator 12 may generate the jittered clock signal 26 based on receiving the phase controlled internal locked clock signal. In any case, the DLL 118 may provide the phase controlled internal clock signal to the I/O interface 106. Moreover, the I/O interface 106 may use the received phase controlled internal clock signal as a clock signal for transmitting the read data using the external bus 112.

In specific embodiments, the jitter generator 12 may include circuitry to operate in a variety of operational modes. In different operational modes, the jitter generator 12 may transmit different jittered clock signals to different components based on the clock signal 22 and/or multiple different clock signals. For example, the jitter generator 12 may operate in a first operational mode to transmit the jittered clock signal 26 to the command decoder 120 and may operate in a second operational mode to transmit a phase controlled jittered clock signal to the DLL 118.

In some embodiments, the jitter generator 12 may operate in a pass-through mode to enable the clock signal 22 to pass-through without having jitter added to the clock signal 22 by the jitter generator 12. In this way, the jitter generator 12 may receive and output the clock signal 22 to the command decoder 120 without inducing and/or adding jitter to the clock signal 22. In such embodiments, the command interface 104, and/or a controller or processing circuitry of a host device (e.g., a processing subsystem), may instruct the jitter generator 12 to operate in at least these described operational modes.

Although in the depicted embodiment, the jitter generator 12 is coupled to the command interface 104, the multiplexer 16, the command decoder 120, and the DLL 118, it should be appreciated that in alternative or additional embodiments, the jitter generator 12 may be coupled to different circuit components of the memory device 100. Moreover, alternatively or additionally, the jitter generator 12 may provide the jittered clock signal 26 to a reduced number of the circuit components, additional circuit components of the memory device 100, and/or additional circuit components not shown in the depicted embodiment.

In any case, the jitter generator 12 may output the jittered clock signal 26 to a first input of the multiplexer 16. Moreover, the command interface 104 may output the clock signal 22 to a second input of the multiplexer 16. In alternative or additional embodiments, the jitter generator 12 may provide the clock signal 22 to the second input of the multiplexer 16. In turn, the multiplexer 16 may output the clock signal 22 or the jittered clock signal 26 to the I/O interface 106. For example, the I/O interface 106 may include the input/output circuit 20 discussed above. The multiplexer 16 may receive the selection signals 30 indicative of outputting the clock signal 22 or the jittered clock signal 26 to the I/O interface 106.

In the depicted embodiment, the command interface 104 may provide the selection signals 30. For example, the memory controller 108 may provide one or more signals indicative of providing the selection signals 30 to the command interface 104. Alternatively or additionally, any viable circuit component may provide the selection signals 30 to the multiplexer. The I/O interface 106 may latch outgoing data (e.g., the output data 28) based on receiving the clock signal 22 to correct the distorted margins of the outgoing data (e.g., the output data 28). Alternatively, the selection signals 30 may indicate outputting the jittered clock signal 26 to the input/output circuit 20. In any case, the input/output circuit 20 may provide the outgoing data to one or more external devices.

The command decoder 120 may receive the access commands via a bus 122 and/or through the I/O interface 106 received via the external bus 112. For example, the command decoder 120 may receive the access commands through the I/O interface 106 transmitted by one or more external devices. In some cases, a processor may transmit the access commands.

The command decoder 120 may decode the access commands and/or the memory access requests to provide corresponding access instructions for accessing target memory cells. For instance, the command decoder 120 may provide the access instructions to one or more control blocks 136 associated with the memory banks 102 via a bus 126. In some cases, the command decoder 120 may provide the access instructions to the control blocks 136 in coordination with the DLL 118 over a bus 124. For example, the command decoder 120 may coordinate generation of the access instructions in-line (e.g., synchronized) with the jittered clock signal 26, the clock signal 22, and/or the phase controlled internal clock signal.

Accordingly, the command decoder 120 may decode the access commands (e.g., memory access requests) to provide the access instructions. In some cases, the command decoder 120 may receive the access commands using a rising edge and/or a falling edge of the external clock signal. For example, a processor may transmit the access commands using a memory command protocol such as the multi-clock cycle memory command protocol. Moreover, the processor may use a specific memory command protocol based at least in part on the number of pins of the memory device 100 or the I/O interface 106, the number of memory banks 102, the number of rows and/or columns of the memory banks 102, and/or a bandwidth of the memory device 100 for communication with one or more of the memory banks 102.

Subsequently, the command decoder 120 may provide the access instructions to the memory banks 102 based on the jittered clock signal 26. In particular, the command decoder 120 may receive and decode the access commands based on the jittered clock signal 26. Accordingly, the command decoder 120 may provide the access instructions to the memory banks 102 using one or multiple clock cycles of the jittered clock signal 26 via the bus 126. The command decoder 120 may also transmit various signals to one or more registers 128 via, for example, one or more wiring lines 130.

In some embodiments, the memory device 100 may include control blocks 136. In such embodiments, each memory bank 102 may be associated with or include a respective control block 136. In some cases, each of the control blocks 136 may also provide row decoding and column decoding capability based on receiving the access instructions. For example, the control blocks 136 may receive the access instructions with jittered frequency based on operations of the command decoder 120. As mentioned above, the command decoder 120 may receive and decode the access commands based on receiving the jittered clock signal 26.

Accordingly, the control block 136 may facilitate accessing the memory arrays of the respective memory banks 102. For example, the control blocks 136 may include circuitry (e.g., row decoders, column decoders, transceivers, and/or data lines, among other things) to facilitate accessing the memory cells of one or more memory arrays of the respective memory banks 102 based on receiving the access instructions. Moreover, the row decoders, column decoders, transceivers, and/or data lines of the control blocks 136 may facilitate accessing the memory cells of one or more memory arrays based on receiving the access instructions with jittered frequency.

In some cases, the control blocks 136 may receive the access instructions and determine target memory banks 102 associated with the target memory cells. In specific cases, the command decoder 120 may include the control circuitry 134 and/or the control blocks 136. Moreover, the control blocks 136 may also provide timing control and data control functions to facilitate execution of different commands with respect to the respective memory banks 102.

Furthermore, the command decoder 120 may provide register commands to the one or more registers 128 to facilitate operations of one or more of the memory banks 102, the control circuitry 134, the control blocks 136, and the like. For example, one of the one or more registers 128 may provide instructions to configure various modes of programmable operations and/or configurations of the memory device 100. The one or more registers 128 may be included in various semiconductor devices to provide and/or define operations of various components of the memory device 100.

In some embodiments, the one or more registers 128 may provide configuration information to define operations of the memory device 100. For example, the one or more registers 128 may include operation instructions for DRAMs, synchronous DRAMs, FeRAMs, chalcogenide memories (e.g., SSM memory, PC memory), or other types of memories. As discussed above, the one or more registers 128 may receive various signals from the command decoder 120, or other components, via the one or more wiring lines 130. The additional registers may involve additional wiring across the semiconductor device (e.g., die), such that the registers are communicatively coupled to the corresponding memory components.

The I/O interface 106 may include a number of pins (e.g., 7 pins, 10 pins, 25 pins, etc.) to facilitate data communication with external components (e.g., the processing component, such as a processor). Moreover, the I/O interface 106 may include a number of I/O pads 140 to facilitate data communication according to one or more communication standards. In some cases, each I/O pad 140 may convert a data type (e.g., frequency, data rate, etc.) between the memory device 100 and one or more external devices. For example, the I/O pads 140 may include a Low-Power Double Data Rate (LPDDR), among other possibilities.

In any cases, the I/O interface 106 may receive the access commands via the pins. Moreover, data stored on the memory cells of the memory banks 102 may be transmitted to and/or retrieved from the memory banks 102 via the control blocks 136 over the data path 138. The data path 138 may include a plurality of bi-directional data buses to one or more external devices via the I/O interface 106. For example, the control blocks 136 may be electrically coupled via row buses and column buses of the data path 138. In some embodiments, the data path 138 (or the bus 126) may include a common data path, a common address path, a common write command path, and a common read command path. The data path 138 may traverse across the memory device 100.

With the foregoing in mind, it should be appreciated that the memory device 100 may include additional or alternative components. For example, the memory device 100 may include additional or alternative components such as power supply circuits (for receiving external VDD and VSS signals), read/write amplifiers (to amplify signals during read/write operations), temperature sensors (for sensing temperatures of the memory device 100), among other things.

FIG. 4 depicts an embodiment of a memory system 160 including multiple electronic devices 10 such as the memory devices 100. For example, the depicted embodiment of the memory system 160 may include a DIMM and/or a RAM device. Although a specific architecture of the memory system 160 is depicted in FIG. 4, it should be appreciated that the depicted embodiment is merely an example and various suitable architectures may be used in different embodiments of the memory system 160. Furthermore, in the depicted embodiment, each of the memory devices 100 may include a DRAM device. However, it should be appreciated that in other embodiments, each of the memory devices 100 may include an FeRAM device, a SRAM device (including a double data rate SRAM device), flash memory, and/or a 3D memory array including phase change (PC) memory and/or other chalcogenide-based memory, such as SSM, among other things.

In some cases, the memory system 160 may be coupled to a computing system via an edge connector 162. The edge connector 162 may couple to or include a number of data pins 164 and/or strobe signal pins. Moreover, the edge connector 162 may couple to a system bus to communicate data with external devices via the data pins 164 via the edge connector 162.

In the depicted embodiment, the memory system 160 may include a power management integrated circuit (PMIC) 166 and a registering clock driver (RCD) 168. The PMIC 302 may control a power supplied to the memory devices 100. In some cases, the RCD 168 may provide a clock signal having a core clock frequency (e.g., the core clock frequency 70) to each of the memory devices 100. Alternatively or additionally, the RCD 168 may provide different clock signals to different memory devices 100 of the memory system 160.

One or more of the memory devices 100 may include the jitter generator 12 discussed above. As such, at least some of the memory devices 100 may perform memory operations using the jittered clock signal 26 (e.g., an operating jittered clock frequency) based on a received clock signal from the RCD 304. Moreover, each of the memory devices 100 including a jitter generator 12 may generate a different jittered clock signal 26. As such, the memory devices 100 including the jitter generator 12 may each generate a different jittered clock signal 26.

As mentioned above, the electronic devices 100 operating based on a different jittered clock signal may each emit the undesired electromagnetic signals having different frequencies during operation. For example, the jittered clock signals may each have a different clock frequency compared to a core clock frequency (e.g., ±1 Hertz (Hz), ±3 Hz, ±50 Hz, and so on). As such, a cumulative peak emission power of the memory system 160 may be reduced during operation. Accordingly, inducing jitter to the clock signal of one or multiple electronic devices may improve operations of the one or more electronic devices 100 and/or the memory system 160 by reducing the electromagnetic interference of the one or more electronic devices 100.

A technical benefit of inducing jitter to the clock signals of the memory devices may include improving reliability of the memory devices and the memory systems including such memory devices. As such, an error rate of such memory devices and/or memory systems may be reduced. Moreover, in some embodiments, such memory devices and/or memory systems may include reduced circuitry for improving undesired electromagnetic emissions of an electronic device and/or electronic system based on including the jitter generator 12, as discussed above. In such embodiments, the electronic device and/or electronic system may occupy a reduced circuit area based on including the reduced circuitry.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. An electronic device, comprising:
a clock input buffer configured to receive a clock signal;
a jitter generator coupled to the clock input buffer, wherein the jitter generator is configured to generate a jittered clock signal based on receiving a clock signal;
control circuitry coupled to the jitter generator, wherein the control circuitry is configured to generate output data based on receiving input data and the jittered clock signal; and
input/output circuit configured to provide output data to one or more external devices responsive to the clock signal.

2. The electronic device of claim 1, wherein the input/output circuit provide the output data by latching the output data with the jittered clock signal.

3. The electronic device of claim 1, wherein the jittered clock signal is configured to comprise the clock signal having induced jitter thereon.

4. The electronic device of claim 1, wherein the jittered clock signal is configured to have a jittering frequency within a frequency range.

5. The electronic device of claim 4, wherein the frequency range comprises a frequency of the clock signal.

6. The electronic device of claim 1, wherein the control circuitry comprises a memory device comprising one or more memory banks.

7. The electronic device of claim 6, wherein the one or more memory banks are configured to receive the input data and provide the output data based on receiving the jittered clock signal.

8. The electronic device of claim 1, comprising a multiplexer coupled to the clock input buffer, the jitter generator, and the input/output circuit, wherein the multiplexer is configured to provide the clock signal or the jittered clock signal to the input/output circuit.

9. The electronic device of claim 8, wherein the input/output circuit provide the output data by latching the output data based on receiving the clock signal or the jittered clock signal.

10. A memory device, comprising:
one or more memory banks configured to store and retrieve data;
a jitter generator configured to provide a jittered clock signal based on receiving a clock signal;
an input/output interface configured to receive input data and provide output data;
a command decoder coupled to the one or more memory banks, the jitter generator, and the input/output interface, wherein the command decoder is configured to provide access instructions to the one or more memory banks to store or retrieve the data based on receiving the input data and the jittered clock signal.

11. The memory device of claim 10, wherein the command decoder is configured to provide the output data based on receiving the jittered clock signal.

12. The memory device of claim 10, wherein a frequency of the jittered clock signal comprises a frequency of the clock signal having positively and negatively induced frequency jitter values.

13. The memory device of claim 10, wherein the jittered clock signal is configured to have a jittering frequency within a frequency range, wherein the frequency range comprises a frequency of the clock signal.

14. The memory device of claim 13, comprising a multiplexer coupled to the jitter generator and the input/output interface, wherein the multiplexer is configured to provide the clock signal or the jittered clock signal to the input/output interface.

15. The memory device of claim 14, wherein the input/output interface is configured to provide the output data by latching the output data based on receiving the clock signal or the jittered clock signal.

16. A memory system comprising:
a registering clock driver configured to provide a clock signal having a core clock frequency;
a plurality of memory devices coupled to the registering clock driver, wherein the memory devices each comprise:
one or more respective memory banks configured to store and retrieve data;
a respective jitter generator configured to provide a respective jittered clock signal based on receiving the clock signal;
a respective input/output interface configured to receive input data and provide output data; and
a respective command decoder coupled to the one or more respective memory banks, the respective jitter generator, and the respective input/output interface.

17. The memory system of claim 16, wherein the respective command decoder is configured to provide access instructions to the one or more respective memory banks to store or retrieve the data based on receiving the input data and the respective jittered clock signal and provide the output data based on receiving the respective jittered clock signal.

18. The memory system of claim 16, wherein a frequency of each respective jittered clock signal comprises a frequency of the clock signal having positively and negatively induced frequency jitter values.

19. The memory system of claim 16, wherein each respective jittered clock signal is configured to have a jittering frequency within a frequency range, wherein the frequency range comprises a frequency of the clock signal.

20. The memory system of claim 16, wherein each memory device comprises a multiplexer coupled to the respective jitter generator and the respective input/output interface, wherein each respective multiplexer is configured to provide the clock signal or the respective jittered clock signal to the respective input/output interface, wherein each respective input/output interface is configured to provide the output data by latching the output data based on receiving the clock signal or the respective jittered clock signal.
